(19) United States
(12) Patent Application Publication
(10) Pub. No.: US 2026/0005189 A1
(43) Pub. Date: Jan. 1, 2026

(54) METHOD OF BONDING A FIRST SUBSTRATE TO A SECOND SUBSTRATE, BONDING APPARATUS AND ASSEMBLY OF FIRST AND SECOND SUBSTRATES

(71) Applicant: EV Group E. Thallner GmbH, ST. FLORIAN AM INN (AT)

(72) Inventors: Markus WIMPLINGER, St. Florian am Inn (AT); Christian MÜHLSTÄTTER, St. Florian am Inn (AT)

(21) Appl. No.: 18/880,640

(22) PCT Filed: Jul. 1, 2022
(86) PCT No.: PCT/EP2022/068275

§ 371 Date: Jan. 2, 2025

(51) Int. Cl. H01L 23/00

(52) U.S. Cl. CPC H01L 24/80; H01L 24/74; H01L 2224/74; H01L 2224/80006; H01L 2224/80895; H01L 2224/80896

(57) ABSTRACT

A method of bonding a first substrate (2u) to a second substrate (2o), the first substrate
(2u) having a primary section and the second substrate (2o) having a secondary section, wherein when the first substrate (2u) is bonded to the second substrate (2o), a bond wave (3) advancing along a bonding direction is formed between
a first partial portion, in which the first substrate (2u) and the second substrate (2o) are bonded, and
a second partial portion, in which the first substrate (2u) and the second substrate (2o) are still to be bonded,

wherein preferably a subsection of the second substrate (2o) in the second partial section is vertically offset with respect to a subsection of the second substrate (2o) in the first partial portion in a direction perpendicular to a main extension plane, and

wherein for the relative alignment of the primary section and the secondary section with respect to one another, in particular with respect to a direction running essentially parallel to the bonding direction, a first curvature of the first substrate (2u) and/or a second curvature of the second substrate (2o) is modified by means of a deformation system in a region adjacent to the bond wave (3) and/or in a region including the bond wave (3).

The present invention relates to a method of bonding a first substrate to a second substrate, an apparatus for bonding, and an assembly of the first and second substrates.

In the semiconductor industry, several different processes exist to connect substrates, especially wafers, with each other. The connection process is called bonding. The bonding process may either be temporary or permanent. A temporary bond is usually only used to bond a product substrate to a carrier substrate in order to be able to process it. A permanent bond is used to permanently bond two substrates. The substrates to be bonded are preferably product substrates. Each of the product substrates generally already has structures, in particular entire functional units such as microchips, memory chips, LEDs, MEMS, etc. Permanent bonding allows product substrates with different functional units to be combined to a substrate stack.

It is conceivable, for example, that there are several microchips on a first product substrate and several memory chips on a second product substrate. By suitably designing the functional units on both product substrates, it is possible to assign a memory chip to each microchip. Preferably, the connection between the functional units beyond the bond interface is established via the contact interface of two vias. Since the substrate surfaces are directly bonded together, this is also referred to as a direct bond. A special type of direct bond is a fusion bond. A fusion bond is a direct bond of dielectric substrate surfaces, in particular substrate surfaces made of oxide.

A particularly important fusion bond is a hybrid bond. A hybrid bond is a bond between two substrate surfaces consisting of electrical and dielectric regions. The dielectric regions are usually an oxide, in particular a silicon oxide. The silicon oxide is opened in several places by different process steps. The openings are mostly radially symmetrical openings. These openings are then filled with a metal. The metal extends to the functional units that have been buried under the dielectric layer and represent the outward reaching contacts. After the fabrication process, a substrate surface having a primarily dielectric region and multiple, small, distributed electrical regions remains. Several such substrates can then be aligned and contacted to each other by a hybrid bond. It is fundamental that the metallic regions contact each other correctly, as otherwise no electrical contact is established between the functional elements. The metallic areas are called via (pl. vias). If the vias also pass through silicon, they are usually called through-silicon vias (TSVs). The surfaces of through-silicon vias are the most important types of structures that must be brought into congruency in a fusion bonding process, since it is through them that the electrical contacting of the various functional units takes place.

With the increasing use of fusion bonds, especially hybrid bonds, for the production of “next-generation” semiconductor chips, there is a need to continuously improve the quality of bonding results. A key quality criterion for bonded substrates is the precision of the position of the structures, especially the vias. This is referred to as the “overlay”. This basically means the actual position of the structures compared to the expected position of the structures.

In the entire semiconductor industry, structures are manufactured the structure sizes of which are in the micrometer and now already in the nanometer range. Transistors, for example, have structure sizes in the nanometer range. TSVs can have structure sizes in the micrometer range. Entire microchips have structure sizes in the millimeter or micrometer range.

All structures are developed and digitally stored using software. This means that every structure created on the substrate in a subsequent manufacturing process has a well-defined, exact position and size in the computer in the beginning. This idealized state is referred to below as the nominal state.

In order to create the structures on a substrate, several dozen, sometimes even several hundred process steps are necessary. Each process step can generally only be performed with a certain accuracy or is subject to error. For example, the diffraction limit is a classic example of the maximum achievable accuracy in photolithography when it comes to transferring the structure of a mask into a photoresist. This physical limit can be exhausted, but not circumvented. A typical example of error-prone process would be the backlash in mechanical engineering elements that must perform motion. The mechanical engineering parts cannot be built without backlash and therefore always generate some type of error that ultimately affects the accuracy of the manufactured structures.

Although enormous progress has been made in recent decades to fabricate the structures on a substrate more and more accurately, while at the same time their areal density has continuously increased, it is the case that every fabricated structure on a substrate generally deviates, even if only very slightly, from the nominal state. This real existing state of the structures on a substrate will be referred to as the actual state in the following.

However, the term “overlay” is used much more generally in the semiconductor industry. Overlay is generally understood to be the set of displacement vectors of individual points of a substrate, which represent the displacement of the point from a position before a process step to a position after the process step. Each individual process step of a process can thus lead to a displacement of the structures and thus to an overlay. In this context, the state before the process step is then referred to as the nominal state and the state after the process step as the actual state.

The structures of two substrates to be bonded together are therefore generally not ideal even before the bonding process, but distorted in relation to the nominal state.

Another, much more serious problem arises during the bonding process. In fusion bonding, the bonding process takes place through the propagation of a bond wave. The substrates are initially contacted in a point-like manner, in particular centrically. Then at least one of the two substrates is moved in such a way that the bonding surface between the two substrates can increase and spread. It is conceivable that the upper substrate is dropped, in particular in a controlled manner, or that fixing elements of the upper substrate holder are switched continuously, in particular from the inside to the outside, in such a way that the upper substrate lowers from the contacting point towards the periphery. It would also be conceivable for the two substrate holders, and thus the substrates, to approach each other. A combination of the above possibilities is also conceivable. In any case, a bond wave, starting from the contacting point, advances outward. During this bonding process, several competing forces are formed, particularly along the bond wave. During advancing of the bond wave, these forces lead to a distortion of the lower and/or upper substrate and thus to an undesired deviation between the upper and lower structures, in particular functional units. Even if the structures had been produced in the desired state, which is technically impossible or very difficult, the bonding process would lead to the generation of new distortions.

Another problem is that the distortions generated by the bonding process may not necessarily have a local effect, but a global one. Any distortion at an inner radial position of the substrate generally also has an effect on the bonding result at radial positions located further outward.

Another problem are so-called edge voids. These micrometer-to millimeter-sized defects, which are probably gas inclusions, have been a well-known and troublesome problem in the semiconductor industry for years. The formation of edge voids is still a highly studied phenomenon in technology, and their prevention is a desirable goal.

Another problem is increased distortion at the edge of the substrates. Although distortions generally occur along the entire substrate surface during the bonding process, the distortions at the edge are particularly strong.

Based on this, it is the object of the present invention to avoid the disadvantages known from the prior art or to reduce their effect on the bonding process and the bonded product.

According to the present invention, this object will be achieved by providing a method of bonding a first substrate with a second substrate according to claim 1 and an apparatus for bonding according to claim 7 as well as an assembly according to claim 15. Advantageous further embodiments of the invention are indicated in the dependent claims. Within the scope of the invention are also all combinations of at least two features indicated in the description, in the claims and/or in the drawings. In case of specified ranges of values, values located within the specified limits are also to be regarded as limit values disclosed and are to be claimable in any combination. If features are described in the description and claims for the first substrate and the first substrate holder, these apply analogously to the second substrate and the second substrate holder.

In accordance with a first aspect of the present invention, there is provided a method of bonding a first substrate to a second substrate, the first substrate having a primary section and the second substrate having a secondary section, wherein, when bonding the first substrate to the second substrate, a bond wave advancing along a bonding direction is formed between
a first partial portion, in which the first substrate and the second substrate are bonded, and
a second partial portion, in which the first substrate and the second substrate are still to be bonded,
   wherein preferably a subsection of the second substrate in the second partial section is vertically offset with respect to a subsection of the second substrate in the first partial portion in a direction perpendicular to a main extension plane, and
   wherein for the relative alignment of the primary section and the secondary section with respect to one another, in particular with respect to a direction running essentially parallel to the bonding direction, a first curvature of the first substrate and/or a second curvature of the second substrate is modified by means of a deformation system in a region adjacent to the bond wave and/or in a region including the bond wave.

In contrast to the methods known from the prior art, it is provided in accordance with the invention that the first curvature and/or the second curvature in the region adjacent to the bond wave or in the region comprising the bond wave is modified locally in a controlled manner, in particular immediately prior to bonding the region adjacent to the bond wave. In particular, it is provided that by modifying the first curvature and/or the second curvature, a corresponding adjustment is made which ensures that after the bonding process the primary section and the secondary section are arranged one above the other in a direction perpendicular to the main extension plane, preferably congruent with each other. In other words, the overlay is optimized. In this way, it is advantageously possible to increase a positioning accuracy that ensures that the primary section and secondary section of the first and second substrates are not offset from each other in a direction parallel to the bonding direction. This proves to be particularly advantageous when structures and/or functional units are formed in the primary section and secondary section, respectively, which are to be interconnected, particularly electrically interconnected, with each other in the bonded state. These structures and/or functional units include, for example, vias and/or connections of electrical or electronic components such as MEMS or LEDs.

It has been found that by selectively adjusting the first curvature and/or the second curvature, particularly in the region adjacent to the bond wave or in the region including the bond wave, it is possible to control the positional accuracy, particularly the relative alignment of the primary section and the secondary section, in such a way that the probability of exclusion is significantly reduced. Such an exclusion of the bonded arrangement of first and second substrate occurs when the primary section and secondary section are offset from each other in such a way that, for example, no sufficient connection can be realized between the primary section and secondary section or between the corresponding functional units in the primary section and the secondary section. In particular, it is provided that the first or second curvature is specifically influenced in an area adjacent to the bond wave and/or comprising the bond wave, i. e. specifically in a locally limited area. In particular, it is thus provided that a targeted local influence is exerted on the first or second curvature. A global or globally acting deformation can additionally be provided. Preferably, only the first substrate or the second substrate, i.e. only one of the substrates to be bonded, is influenced by means of a deformation system. This advantageously reduces the number of parameters to be controlled and monitored and limits them to the handling of a single substrate.

In particular, it is provided that the modification of the first and/or second curvature serves to match the first curvature and the second curvature in the region adjacent to the bond wave. Here it is conceivable, for example, that a difference between the first curvature and the second curvature should not exceed a fixed threshold value or should be kept substantially constant. A curvature is to be understood in particular as the reciprocal value of a radius of that circle whose sectional course describes the curved subsection of the first substrate or the second substrate.

The bonding between the first substrate and the second substrate takes place via the substrate surfaces of the first substrate and the second substrate, which are brought into contact with each other during the bonding process.

The main extension plane is preferably defined by a support surface of a substrate holder, i.e. a first substrate holder and/or second substrate holder. The support surface preferably extends with its general course along the main extension plane. In particular, the main extension plane is defined by the general course of the first partial portion, in particular by the general course of the region of the first partial portion that is not curved or is free of a curvature and runs essentially flat.

The bonding process is characterized in particular by the fact that during bonding the first partial portion, in which bonding has already taken place, is arranged essentially in the main extension plane, while the first substrate and/or the second substrate in the second partial portion is offset in height at least in sections relative to the first partial portion in a direction running perpendicular to the main extension plane. In particular, it is provided that during bonding the first substrate is raised in sections in the region adjacent to the bond wave. Due to a spacing of the second substrate holder from the second substrate holder, the second substrate also has a second curvature in the region adjacent to the bond wave. As a result, a first curvature and a second curvature are already established in the region of the bond wave by the bonding process, without the deformation system having any influence on the first curvature or the second curvature. The modification or an extent of the modification, which originates from the deformation system, is thus determined with respect to the first curvature and/or second curvature, which would have to be determined during the bonding process without a deformation system.

In particular, the region adjacent to the bond wave or the region including the bond wave extends over at least 5 mm, preferably at least 2.5 mm and particularly preferably at least 1 mm. Preferably, it is provided that outside such a dimensioned area the deformation or the modification and effect on the first curvature by the deformation areas or the deformation system or fixing elements is negligibly small. The region adjacent to the bond wave or including the bond wave can extend over the first partial portion and the second partial portion.

Preferably, the bonding is a direct bonding, preferably a fusion bonding and especially preferably a hybrid bonding. The substrates are preferably wafers, for example silicon wafers, which are particularly preferably bonded by the bonding process to form a product substrate or a temporary substrate.

The first curvature and/or the second curvature is preferably adjusted by means of a deformation system comprising coatings, fixing elements and/or deformation means. By fixing elements, the person skilled in the art understands in particular such devices which are provided to hold subsections of the first and/or second substrate. Preferably, the individual fixing elements can be transferred individually or in groups between a fixing state and a release state. In the bonding process, the fixing elements are used to selectively allow subsections of the first substrate and the second substrate to come into contact. For example, individual fixing elements in a second substrate holder are transferred to the release state in order to drop a subsection of the second substrate so as to come into contact with a corresponding subsection of the first substrate. By selectively setting a fixing force, it is also possible to influence the first curvature. In a preferred embodiment, the deformation system is formed at least partially or completely by fixing elements. It is also conceivable that the deformation means is preferably designed exclusively for setting the first curvature and/or the second curvature and, for example, cannot fix or hold the first substrate and/or the second substrate in order to control the bonding process.

A structure is preferably understood by the person skilled in the art to be an object of whatever kind that is produced on a substrate using a wide variety of processes. Examples of a structure would be the smallest units of a transistor, TSVs, but also the functional units defined below. The word structure is therefore used as a generic term. A functional unit is understood by the person skilled in the art to mean in particular a structure that has a functional character, i.e. that can be regarded as an active part. Examples of this would be microchips, memory chips, LEDs, MEMS, etc. By a displacement, the person skilled in the art in particular understands the change in position of a point from a first position to a second position. By a distortion or strain, the person skilled in the art preferably understands, in physical terms, the change in length relative to the initial length. Mathematically, it is the partial derivative of the displacement. By an elongation, the person skilled in the art understands the lengthening of a body due to a distortion or stretching. By a nominal state, the person skilled in the art understands the idealized, in particular computer-generated, calculated and stored set of all structures with their ideal positions or the set of all structures before a process step. By an actual state, the person skilled in the art preferably understands the real, in particular already generated on the substrate, set of all structures with their real positions or the set of all structures after a process step. By an overlay, the person skilled in the art in particular understands a measure for the vector shift of structures from a first process step to a second process step. An overlay is generally represented as a displacement vector field. Each structure on a substrate can be assigned a position at a first process step and at a second process step. The displacement is the difference vector of these two positions and the displacement vector field or overlay is the set of all these difference vectors of all structures.

By a substrate holder, the person skilled in the art preferably understands any component, in particular any group of components, with the aid of which a substrate is fixed and with the aid of which the advancing bond wave can be manipulated. Bond wave is understood to be the set of all interfacial points of two substrates bonding to each other, which delimit the outer regions not yet bonded from the inner regions already bonded. A synonym for bond wave would be bond interface or bond front.

Preferably, the modification of the first curvature and/or the second curvature is carried out via fixing elements. The majority of all substrate holders already have corresponding fixing elements. Substrate holders also already exist which have several, in particular symmetrically distributed, fixing elements, so that position-controlled fixing of the substrate, i.e. of the first substrate and/or of the second substrate, is possible. By selectively controlling a fixing element, in particular before and/or during and/or after the passage of the bond wave over the fixing element, a force effect, and thus the elongation or curvature caused, can be selectively adjusted. If the substrate holder has several fixing elements distributed over the substrate surface, the bond wave can be controlled in a spatially resolved manner.

Preferably, the deformation system comprises a plurality of deformation means arranged along the bonding direction. By means of a plurality of deformation means, which are distributed in particular homogeneously along the bonding direction, it is advantageously possible to exert a local influence on the first curvature and/or second curvature during the entire bonding process, in particular specifically in the respective area to be bonded. For this purpose, it is preferably provided that the deformation means and/or measures are arranged essentially equidistantly to each other along the bonding direction. In the case of a radially propagating bond wave, for example, a radial distance between two adjacent deformation means is essentially constant.

In particular, it is provided that during bonding by means of the deformation system a difference between first and second curvature is kept substantially constant along the bonding direction at least in sections. Preferably, the difference between the first and second curvature is kept constant over a distance which is more than 50%, preferably more than 75% and particularly preferably more than 80% of a bonding distance, the bonding distance being the entire length over which the bonding process takes place. It has been found here that by appropriately matching the first and second curvatures to one another, distortion or an amount of distortion between the first and second substrates can be kept as low as possible, which has a positive effect on any distortions between the first substrate and the second substrate, as well as on positional accuracy when aligning the first substrate and the second substrate with respect to one another. Here, “substantially constant” means that first curvature and/or second curvature deviates no more than 15%, preferably no more than 10%, and particularly preferably no more than 5%, from twice an arithmetic mean value of first curvature and second curvature. Furthermore, it is preferably provided that the various deformation means in the individual deformation areas along the bond distance specifically ensure that the first curvature and second curvature are substantially constant in their sum. In this context, the influence of the individual deformation means may differ from one another. In particular, the deformation means are individualized with regard to their influence or effect for the respective area to be bonded, which is assigned to the individual deformation means.

In particular, it is provided that the deformation system is modified during bonding, for example by means of a control device. For example, it is conceivable that the influence exerted by a single deformation means in a deformation area is controlled in a targeted manner in order to influence the first curvature and/or the second curvature in this way, in particular during the bonding process. This can be done advantageously during the bonding process. This makes it possible, for example, even to react to changes occurring during the bonding process and to adjust the influence accordingly in order to modify the first and/or second curvature. This can preferably be realized, for example, by displaceable components which can be displaced, for example, along a height direction running perpendicular to the main extension plane. In this case, the corresponding components can be arranged in a height-shifted manner by the control device via corresponding controls. It is also conceivable that a coating on the substrate holder can be controlled accordingly, for example via an electrical voltage.

The movable components are controlled or regulated before and/or during and/or after the passage of the bond wave in such a way that a new, in particular geometrically changed, state for the bond wave or the area adjacent to the bond wave is created by raising or lowering the components. In particular, this can create convex and/or concave areas as a function of location. As a result, the distortions are controlled locally in the substrates so that an optimum bonding result is achieved.

Preferably, the deformation system is set before bonding. In particular, the extent to which the first and/or second curvature is influenced in the individual deformation areas is determined as a function of the type of first and/or second substrate and, in particular, preferably by corresponding empirical values. Here, for example, it is possible to resort to previous bonding processes which, for example, on the basis of stress ratios within the arrangement of first and second substrate, make it possible to recognize in which areas during the bonding process a corresponding adjustment of the first and second curvature is advantageous. To gain knowledge of this behavior, the bonded substrates are preferably analyzed after the bonding process to determine the displacements between the structures on the lower and upper substrates as a function of position. Through this information, it is possible to modify the substrate surface of the, in particular, first substrate holder in such a way that the behavior of the bond wave at each point provides a desired, optimal result. Preferably, the deformation system is then used for a batch of first and second substrates to be bonded. For example, the roughness and/or waviness and/or adhesiveness of the substrate holder can already be considered and implemented during the manufacturing of the substrate holder.

For example, the method includes the following steps:

In a first process step of the method, a first substrate is loaded onto a first substrate holder and fixed. In a second process step of the method, a second substrate is loaded onto a second substrate holder and fixed. In a third process step of the method, an alignment of the first substrate with respect to the second substrate is preferably performed, preferably with the aid of corresponding optical devices. In a fourth process step of the method, bonding of the substrate surface of the first substrate to the substrate surface of the second substrate takes place on a substrate holder. In a fifth process step of the method, the bonded substrate stack is removed from the device. In an optional, sixth process step of the method, heat treatment of the substrate stack is performed. The modification of the first curvature and/or the second curvature preferably takes place in the fourth step.

For the method in which the extent of the influence of the deformation is determined in time before bonding, substrate holders with the device features of the substrate holder having a microstructure and/or a coating are particularly suitable. For the method in which the influence on the first curvature takes place during the bonding process, a first substrate holder with a displaceable component proves to be advantageous. The individual devices are presented in detail below.

Preferably it is provided that, to adjust the first curvature, a coating is disposed between the first substrate and a first substrate holder that supports the first substrate during the bonding process. Preferably, the coating is a layer deposited on at least one of the two substrates to be bonded together. The layer is applied to the substrate side opposite the substrate side to be bonded. This substrate side is referred to as the substrate back side. The thickness of the layer is in particular inhomogeneous, i.e. changes as a function of location. Preferably, the layer is not applied over the entire surface of the substrate backside, but only at specially designated locations, but generally at each location with a thickness provided for this purpose. The use of masks makes it particularly easy to coat those areas of the substrate backside that are to be coated. In a preferred embodiment, the coating is an inorganic coating. The layer is preferably applied by a PVD, CVD or PE-CVD process. Particularly preferred, especially by means of PE-CVD, is the deposition of a layer exclusively in the periphery of the substrate, preferably in a circular segment with a circular segment thickness between 1 mm and 10 mm. The exact circular segment thickness depends on the result to be achieved. The layer should preferably consist of one of the following material classes, in particular mentioned materials: Metal, oxide, preferably SiO₂, carbide, preferably SiCN, SiC, and/or nitride, preferably SiCN and/or SiN.

In a particularly preferred embodiment, the inorganic layer is an oxide layer between 10 nm and 5000 nm. The exact thickness of the oxide layer depends on the result to be achieved. In a further development of the embodiment, the layer can be thinned back and/or polished after deposition.

Preferably, the deposition of the coating produces a specific curvature of the substrate, in particular as a function of location, especially in the edge region of the substrate. Preferably, the coating is deposited at elevated temperatures. Upon cooling, the substrate and the coating will generally expand differently because their coefficients of thermal expansion are different. This results in the formation of a bend that compensates for the thermal stresses that occur. This bending then also has an influence on the advancing bond wave in the bonding process.

Another object of the present invention is an apparatus for bonding a first substrate to a second substrate, in particular by means of a method according to the invention, wherein the first substrate comprises a primary section and the second substrate comprises a secondary section, wherein the apparatus is configured that during bonding of the first substrate to the second substrate, a bond wave advancing along a bonding direction is formed between
a first partial portion, in which the first substrate and the second substrate are bonded, and
a second partial portion, in which the first substrate and the second substrate are still to be bonded,
   wherein preferably a subsection of the second substrate in the second partial section is vertically offset with respect to a subsection of the second substrate in the first partial portion in a direction perpendicular to a main extension plane,
   wherein the apparatus for relative alignment of the primary section and the secondary section with respect to each other, in particular with respect to a direction substantially parallel to the bonding direction, comprises a deformation system configured to allow modification of a first curvature of the first substrate and/or a second curvature of the second substrate in a region adjacent to the bond wave and/or in a region including the bond wave. All advantages and properties described for the method can preferably be applied analogously to the apparatus and vice versa.

Preferably, the device comprises a first and/or a second substrate holder. The substrate holders, i.e. the first and/or second substrate holder, have fixing elements. The fixing elements have the primary task of holding and in particular fixing the first substrate and/or the second substrate during the bonding process. By selectively releasing fixing elements or by changing a state in which the fixing element holds or does not hold the substrate, the bonding process can be selectively adjusted in subsections of the first substrate and the second substrate, in particular in such a way that a bonding process is formed along the bonding direction. The fixing elements can be mechanical fixings, in particular clamps, vacuum fixings, in particular with individually controllable vacuum lanes and/or interconnected vacuum lanes, electrical fixings, in particular electrostatic fixings, magnetic fixings, adhesive fixings, in particular gel-pak fixings, fixings having adhesive, in particular controllable, surfaces. The fixing elements are in particular electronically controllable.

Vacuum fixation is the preferred method of fixation. The vacuum fixation preferably comprises several vacuum lanes exiting at the surface of the substrate holder. Preferably, the vacuum lanes are individually controllable. In a preferred embodiment, some vacuum lanes are combined to form vacuum lane segments that can be individually actuated, and therefore evacuated or flooded. However, each vacuum segment is independent of the other vacuum segments. This provides the possibility of constructing individually controllable vacuum segments. The vacuum segments are preferably of annular design. This enables targeted, radially symmetrical fixing and/or release of a substrate from the substrate holder, in particular from the inside to the outside.

In particular, it is envisaged that the first substrate is held in a first substrate holder during bonding, the first substrate holder having fixing areas for fixing the first substrate and deformation areas for adjusting the first curvature. At the same time, it is conceivable that the fixing areas additionally or alternatively influence the first and/or second curvature. This can be realized, for example, by a correspondingly modulable fixing force. Preferably, it is provided that fixing areas and holding areas alternate along the bonding direction at least in sections, preferably over the entire bonding distance. It is preferably provided that between two fixing elements, the area that comes into contact with the substrate surface has a corresponding influence so that the first and/or second curvature assumes a desired value.

Preferably, it is provided that the deformation system comprises a coating. In particular, if an adhesive or non-adhesive medium is applied to the contact surface in sections between two fixing elements, it is thereby possible to influence an adhesion with which the first substrate bears against the contact surface in the corresponding area. This in turn influences the first curvature. This occurs in particular when a second partial portion of the first substrate is raised relative to a first partial portion of the first substrate as part of the bonding process.

Preferably, it is intended to selectively adjust the adhesiveness of the substrate holder surface by means of a coating as a function of location in order to thereby vary the adhesive strength between the substrate and the substrate holder as a function of location. In a particularly preferred embodiment, the adhesiveness would even be switchable or controllable in a location-resolved manner. It is conceivable to use functional polymers modified in the micro-and nanometer range in such a way that the lotus blossom effect known from nature can be simulated. Further developments in research have shown that the use of electric and/or magnetic fields can cause a curvature of these polymer structures to cause them to detach from the object adhering to them. The detachment of these functional polymers from a substrate would result in the van der Waals forces disappearing, making the substrate locally detachable. This enables a switchable, adhesive substrate holder surface. Preferably, the coating is applied to the substrate holder. However, it is also conceivable that the coating is applied to the substrate and is disposed between the substrate and the substrate holder during operation of the device.

Preferably, the deformation system has a microstructure on a contact surface of the first substrate holder. This realizes the roughness at the contact surface. In this context, it is conceivable that the substrate holder surface can be structured differently as a function of location in order to thereby vary the adhesive strength between the substrate and the substrate holder as a function of location. It would be conceivable to manufacture small holes with different geometries that vary in size and/or orientation depending in particular on the position on the substrate holder. The substrate holder could be coated using a photopolymer, for example, so that a photolithographic process can be used to image the pattern into the photopolymer. The photopolymer is then developed and stripped. What is left behind is an etch mask. By using a chemical and/or plasma, the pattern is then etched into the substrate surface. The photopolymer is then removed. What remains is a patterned substrate surface. The pattern is preferably radially symmetrical.

Preferably, it is provided that the deformation system has a displaceable contact surface. This can be done, for example, by means of deformation pins which are mounted in corresponding recesses and can be displaced by a corresponding height as required, in order in this way to support the second partial portion at least in certain areas in such a way that the desired or preferred first curvature and/or second curvature is set. Alternatively, it is conceivable that the displaceable contact surface is formed by a segment in which a plurality of fixing elements are integrated. These displaceable segments can be changed as a whole in a height displaceable manner in the substrate holder. Preferably, corresponding segments are ring-shaped and arranged concentrically to each other. During the bonding process, the height of the individual segments in particular is controlled and adjusted, whereby influence can appropriately be exerted on the first curvature in the region adjacent to the bond wave.

Preferably, the substrate holder has a dynamic, modifiable substrate holder surface. In one embodiment, the substrate holder is constructed of movable segments. The segments may be centrally positioned circular segments. However, it is also conceivable that the centrally positioned circular segments are further azimuthally subdivided so that there are multiple radially and azimuthally divided segments. Each of these segments can be shifted along a direction normal to the substrate holder surface, and thus influence the advancing of the bond wave.

In one embodiment, the substrate holder has controllable or adjustable deformation elements which can be extended over the substrate holder surface. The substrate holder has several, in particular symmetrically distributed, recesses, preferably bores, in which movable deformation elements, in particular pins, are located. These deformation elements can be retracted and extended in a controlled or regulated manner and thus cause a local curvature of the substrate fixed to the substrate holder before and/or during and/or after the advancing bond wave. Since the deformation elements allow more delicate control than the segments of the previous embodiment, the second embodiment may be more advantageous. In addition, such a substrate holder is easier to manufacture and thus more economical. In a very particular embodiment, the deforming elements themselves have fixing elements, in particular a hole via which a vacuum can be generated, so that the deforming elements are capable of locally fixing the substrate resting on the substrate holder and thus of subjecting it not only to compression but also to tension.

Preferably, it is provided that the deformation system has a profiled contact surface. In particular, the individual deformation areas each have a profiled contact surface. By “profiled”, the person skilled in the art in particular understands a concave, convex and/or stepped course, which in this way can influence the adhesion and supporting capacity which, starting from the individual deformation area, acts on the first subsection and/or second subsection. In a further embodiment, it would be possible for the substrate holder surface to be shaped differently as a function of location, in particular convex or concave. It is also conceivable that the substrate holder surface is given a waviness that varies as a function of location. By this shaping, parts of the substrate are already slightly convex or concave shaped as a function of the location. Thus, by a purely geometric processing of the substrate holder surface, the influence of the bond wave running later over the substrate holders can already be achieved before the bonding process. In a further embodiment, the substrate surface has a deviation from flatness at least at the position where the substrates have their first contact, because the second substrate is particularly pressed onto the first substrate by the use of a bond pin. Preferably, this is a dent, in particular a radially symmetrical dent. Preferably, there is also a fixing element in the region of this dent, which promotes the fixing of the first substrate. The first substrate is thus drawn into the dent. Due to this local generation of a curvature, the substrate surface of the first substrate to be bonded is compressed at least at its minimum. Preferably, therefore, a distortion, in particular a compression, is introduced before the bond even begins. After the bond has been fully completed, the fixing elements of the first substrate holder are switched off. The first substrate will stretch the inherently bonded second substrate a bit. This will then cause the stretching to be increased in that region where the bond wave has just begun to run, and ideally will then be the same as the stretching experienced by the second substrate in those regions where the bond wave had a steady state. It has been shown that by applying such a distortion before bonding, the bonding result can be optimized and improved.

Preferably, it is provided that the deformation areas have a different influence on the first substrate. For example, it is conceivable that in the case of displaceable segments or pin elements, the respective set height of the individual deformation areas is different. In particular, it is provided that the displaceable deformation are only displaced during the bonding process and that there is not already a displacement as soon as the bonding process is started.

In particular, the first substrate holder has an elevation in the edge region. This elevation is designed, for example, as a fully closed base. This structural feature serves in particular to eliminate or at least reduce the edge-voids and the distortions that occur increasingly at the edge. The increase is greater than 10 nm, preferably greater than 500 nm, more preferably greater than 1000 nm, most preferably greater than 2500 nm, most preferably greater than 5000 nm. In most cases, the upper substrate of an upper substrate holder is deformed by a bond pin and brought into contact with the lower substrate. During this deformation process, the substrate surface of the second substrate to be bonded is stretched. The second substrate thus exhibits a convex curvature when viewed from above the substrate surface of the second substrate to be bonded. In order to accommodate this stretching, it is advantageous to compress the substrate surface of the first substrate to be bonded. The first substrate therefore has a concave curvature when viewed from above the substrate surface of the first substrate to be bonded. The substrate resting on the elevation is thus distorted, in particular compressed, in the edge region on its substrate surface to be bonded.

This is necessary because the deformation of the second substrate in the contact point of the bond wave towards the edge is lower due to the mechanical resistance of the wafer (due to shorter remaining unbonded length) and an easier outflow of air from the bonding interface.

Another object of the present invention is an assembly comprising a first substrate and a second substrate, which is manufactures by a method according to the invention. All advantages and properties described for the apparatus and the method can be transferred analogously to the assembly and vice versa.

Further advantages and features will arise from the following description of preferred embodiments of the object according to the invention while reference is made to the accompanying figures. Individual features of the individual embodiment can thereby be combined with each other within the scope of the invention, wherein in the figures

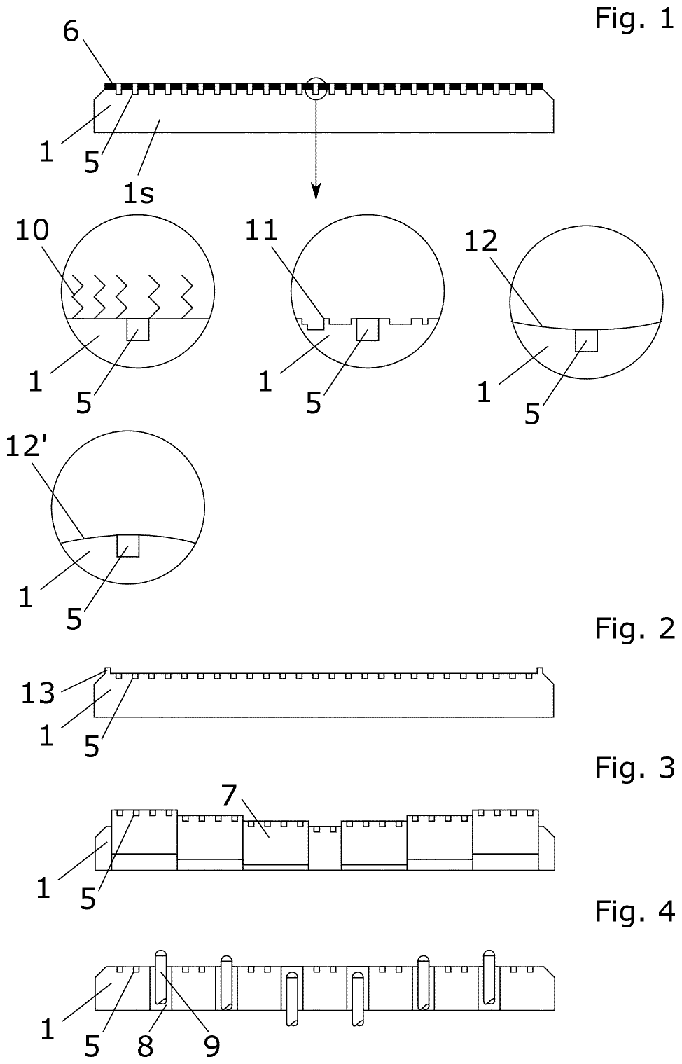

FIG. 1 is a side view of a substrate holder according to a first exemplary embodiment of the present invention,

FIG. 2 is a side view of a substrate holder according to a second exemplary embodiment of the present invention,

FIG. 3 is a side view of a substrate holder according to a third exemplary embodiment of the present invention,

FIG. 4 is a side view of a substrate holder according to a fourth exemplary embodiment of the present invention,

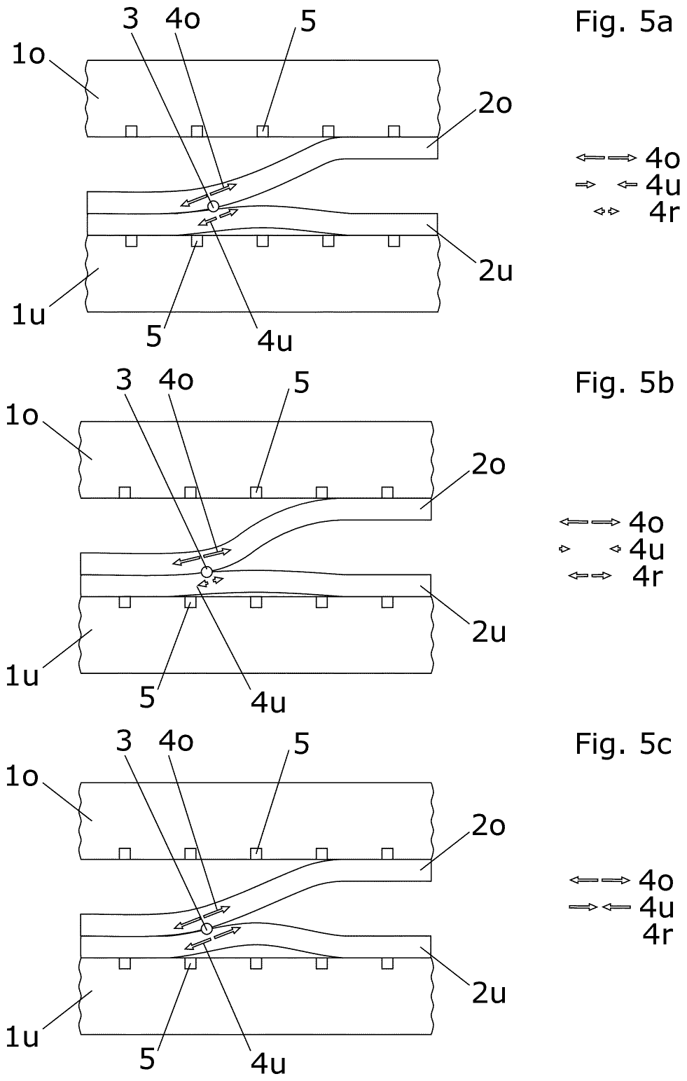

FIG. 5 is a side view of an area during the bonding process at low fixation, and

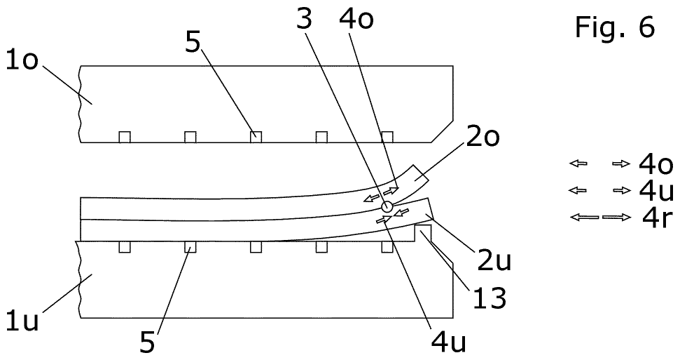

FIG. 6 is a side view of an area during the bonding process with strong fixation.

In the figures, identical components or components with the same function are indicated with the same reference numbers. The figures are purely functional and schematic. The features in the figures are not to scale. In particular, some feature are shown exaggeratedly large to improve clarity and understanding. Correct sectional views are omitted to improve clarity.

The fixing elements 5 in the following figure descriptions are for example and preferably vacuum fixings. The regulation of the holding force of a substrate can be generated and illustrated here particularly clearly by the strength of the suction force. However, all other types of fixing elements are conceivable, in particular electrostatic fixations

FIG. 1 shows a schematic side view of a first embodiment of a substrate holder 1, which has several fixing elements 5, which are arranged in particular in different fixing areas. The substrate holder 1 is used in an apparatus for bonding or joining a first substrate 2u and a second substrate 2o. In this regard, the substrate holder 1 receives one of the substrates 2u, 2o to be bonded in the operating state. Preferably, the individual fixing elements 5 can be transferred individually or in groups between a fixing state and a release state. As a result, a bonding direction can also be determined with advantage, along which the first substrate 2u and the second substrate 2o are bonded to each other. In this case, a bonding process evolves along the bonding direction, wherein a first partial portion that has already been bonded and a second partial portion that is yet to be bonded are separated from each other by a bond wave 3. During the bonding process, the bond wave 3 moves along the bonding direction.

In addition to the fixing areas, the substrate holder 1 comprises a deformation system. The deformation system preferably comprises several deformation areas, in each of which a deformation measure, in particular a deformation means, is provided. The deformation system is preferably designed to selectively adjust a curvature of the substrate 2u, 2o locally in an area adjacent to the bond wave 3. In this context, the adjacent region relates to the region in front of the bond wave 3, i.e. the region that is immediately about to be bonded. Preferably, the adjacent region extends over a distance of up to 5 mm. Preferably up to 2.5 mm and particularly preferably up to 1 mm in front of the bonding section. In other words, the deformation system is designed to act locally, in a targeted manner, on the partial region of the substrate 2a, 2u that is located immediately upstream of the bond wave 3. In particular, the deformation system provides for a deformation area in which the adjacent region is arranged straight and which selectively acts on the substrate 2o, 2u so as to adjust its curvature prior to bonding. Preferably, it is provided that a plurality of deformation areas is formed along the bonding direction, which can selectively influence the curvature of the substrate 2o, 2u when the region adjacent to the bond wave 3 enters the respective deformation area during bonding. In this way, the curvature of the substrate during bonding can be adjusted in a location-dependent manner for each subsection of the substrates to be bonded. In one embodiment, the deformation areas are formed by the fixing areas, in particular when the curvature of the substrates is influenced by means of the fixing elements.

The substrate holder surface 1s of the substrate holder 1 has been modified to form a modified substrate surface or modified contact surface 6. The contact surface 6 comprises a plurality of deformation areas. In the example shown in FIG. 1, the deformation areas and fixing areas alternate. For example, it is intended that the contact surface 6 forms a deformation area between two fixing elements. By means of the modification of the contact surface 6, influence is then exerted on the curvature of the substrate 2o, 2u during bonding. In particular, the contact surfaces 6 in the respective deformation areas are modified in such a way that they increase or reduce an adhesion between contact surface 6 in the deformation area and substrate 2u, 2o. A modification of the contact surface 6 can also cause a partial section of the substrate to be raised or lowered.

Different modifications are shown as enlargements below the substrate holder 1.

The first type of modification can be made by a coating 10, in particular by polymers. The coating influences the adhesion strength between the substrate holder 1 and a fixed substrate 2 (not shown), in particular during the advancement of a bond wave in a bonding process. The physical properties of the coating 10 may change as a function of location and thus provide a locally resolved influence on the bonding process, particularly in the region adjacent to the bond wave.

The second type of modification represents a structured substrate surface 11. A fixed substrate 2 (not shown) has more or less contact with the substrate holder 1 depending on the design of the structured substrate surface 11 and is thus fixed to a greater or lesser extent. This embodiment is also intended to include the principle of roughness, i.e., the unevenness occurring in the nanometer and/or micrometer range.

The third and fourth types of modification represent a concave curvature 12 and a convex curvature 12′. These curvatures 12, 12′ may have different radii of curvature at different positions of the substrate holder 1. If a substrate 2 (not shown) is pulled by a fixing element 5 into a concave curvature 12, for example, the substrate surface to be bonded is compressed. On the other hand, if a substrate 2 (not shown) rests on a convex curvature 12′, its substrate surface to be bonded is stretched. This makes it possible to adjust the distortion state in a locally resolved manner. The curvatures 12, 12′ are shown in the figure as locally limited. However, it is also conceivable that the convex and/or concave curvatures extend over larger areas of the substrate holder 1, in particular thus comprise several fixing elements 5. It is also conceivable that the entire substrate holder surface 1s has only one well-defined concave curvature 12 or convex curvature 12′. In this macroscopic case, this may also be addressed as waviness.

FIG. 2 shows a schematic side view of a second embodiment of a substrate holder 1. The substrate holder 1 has an elevation 13 at its periphery. The elevation 13 can, for example, be designed as a fully enclosed base. It is also conceivable that several such isolated and separated elevations 13 are located along a closed curve. The function of the elevation 13 is to slightly raise a substrate 2 (not shown) at the edge. This slight elevation distorts, in particular compresses, the substrate surface to be bonded.

FIG. 3 shows a schematic side view of a third embodiment of a substrate holder 1. The substrate holder 1 has several segments 7 that can be moved independently of each other. The centrally located segment 7 is preferably circular. The other segments 7 may be circular segments. It is also conceivable that they are segments 7 that are also separated from each other in the azimuthal direction.

FIG. 4 shows a schematic side view of a fourth embodiment of a substrate holder 1. The substrate holder 1 has several deformation elements 9 which can move in recesses 8, preferably bores. The deformation elements are controllable or adjustable. The fixing elements 5 in turn serve to fix the substrate 2 (not shown), while the deformation elements 9 can introduce distortions into the substrate 2 (not shown).

The following two figures illustrate the physical principle of the bonding process as possible with the substrate holders 1 described above. All preferred methods can be traced back to the basic idea that the deviation between the structures of a substrate surface of a first substrate to be bonded and the structures of a substrate surface of a second substrate to be bonded are minimal if it is possible to influence the advancing bond wave 3 during the bonding process in such a way that the distortions 4o, 4u which occur are the same. This goal is achieved in particular by adjusting the distortions 4 in a substrate surface of at least one, preferably the lower, substrate. Influencing a distortion 4, in particular the distortion 4u of the first substrate 2u, is more expedient and easier to control.

All considerations shown always refer to one point of the interface between the two substrates 2u, 2o and is preferably performed for all points of the interface. The shown distortions 4u 4o refer to the substrate surfaces of the substrates 2u, 2o to be bonded, but are shown in the center of the substrates 2u, 2o for clarity.

FIG. 5a shows a schematic side view of a bonding process between two substrates 2u, o along the advancing bond shaft 3.

The lower substrate 2u was loaded and fixed on a lower substrate holder 1u, and the upper substrate 2o was loaded and fixed on an upper substrate holder 1o. A right partial area of the bonding process is shown. The bond wave 3 is shown only as a dot in the side view. The bond wave 3 advances from left to right in the side view. It can be seen that the upper substrate 2o on the left side has already been bonded to the lower substrate 2u in the first partial portion, while it is still held by the upper substrate holder 1o on the right side in the second partial portion.

This causes a local lift-off of the lower substrate 2u from the lower substrate holder 1u due to the force conditions prevailing around the bond shaft 3. The lower substrate 2u lifts off from the lower substrate holder 1u by only a few nanometers or micrometers, or at worst millimeters. This local lift-off also creates local distortions 4u, 4o in the lower substrate 2u and/or in the lower substrate 2o.

FIG. 5b shows a schematic side view of a bonding process between two substrates 2u, 2o along the advancing bond wave 3, in which the lift-off of the lower substrate 2u from the substrate holder 1 is less pronounced than in FIG. 5a. This is due to the influence of a deformation area which influences the first curvature. It is conceivable and preferred that the lower substrate 2u is simply prevented from its greater lift-off by a stronger fixing action of the fixing element 5. This would be the easiest method to implement, since virtually all substrate holders 1 have fixing elements 5. Conceivably, the substrate surface could have been modified to exert a greater adhesive effect at this point. It is conceivable that the substrate surface has been coated and thus the adhesive effect is higher.

In contrast to FIG. 5a, the lower substrate 2u does not lift so far from the lower substrate holder 1u because the corresponding fixing force is stronger. As a result, the bonding process also produces smaller distortions 4u in the lower substrate 2u. In general, the distortions 4o in the upper substrate 2o may also change. To better illustrate the bonding process, it is assumed that the distortions 4o in the upper substrate 2o do not change or change negligibly. This allows a particularly simple comparison of the distortion ratios between FIG. 5a and FIG. 5b.

FIG. 5c shows a schematic side view of a bonding operation between two substrates 2u, 2o along the advancing bond wave 3, where the lift-off of the lower substrate 2u from the substrate holder 1 is more pronounced than in FIG. 5a. This is due to the influence of a deforming means which influences the first curvature. It is conceivable that the lower substrate 2u experiences a greater lift-off simply due to a weaker fixing action of the fixing element 5, because it can be pulled upwards more easily by the upper substrate 2o. This proves to be a comparatively simple way of implementing the method, since virtually all substrate holders 1 have fixing elements 5. It is conceivable that the substrate surface has been modified and that a lower adhesion effect prevails at this point. It is conceivable that the substrate surface has been coated and thus the adhesive effect is lower. In contrast to FIG. 5a, the lower substrate 2u lifts further from the lower substrate holder 1u because the corresponding fixing force is weaker. As a result, the bonding process also creates larger distortions 4u in the lower substrate 2u. In general, the distortions 4o in the upper substrate 2o may also change. To better illustrate the bonding process, it is assumed that the distortions 4o in the upper substrate 2o do not change or change negligibly. This allows a particularly simple comparison of the distortion ratios between FIG. 5a and FIG. 5c.

On the right side of FIGS. 5a to 5c, the resulting distortions 4o of the upper substrate and the resulting distortions of the lower substrate 4u are shown again. The distortions of the upper substrate 4o were adopted in terms of direction. The distortions 4u of the lower substrate were rotated and parallel-shifted to the peaks of the upper distortions 4o. A distortion 4u of the lower substrate 2u distorts the structures (not drawn) on the lower substrate 2u. However, the same happens by the distortions 4o with the structures (not drawn) at the upper substrate 4o. Therefore, one conveniently defines a resulting distortion 4r, which is the difference between the two distortions 4u and 4o. This resulting distortion 4r is not necessarily equivalent to a mechanical distortion in the sense of strain, but is a measure of the deviation of the positions of the structures (not shown in the figures) between the lower substrate 2u and the upper substrate 2o.

FIG. 6 shows a schematic side view of a bonding process between two substrates 2u, 2o along the advancing bond wave 3, in which the bond wave 3 is already very close to the edge of the substrates 2u, 2o. Preferably, by the elevation 13, the distortion 2u of a lower substrate 2u can be adjusted to produce a resulting distortion 4r with the distortion 4o of the upper substrate that is desired. This embodiment is especially important to eliminate or at least reduce edge voids.

In reality, it will not be possible to completely reduce the resulting distortions 4r. Preferably, the aim is that the resulting distortions 4r are at least homogeneous, i.e. the same at each position, at least in in amount.

### LIST OF REFERENCE NUMBERS

1 substrate holder
1u first substrate holder
1o second substrate holder
1s substrate holder surface
2u first substrate
2o second substrate
3 bond wave
4, 4o, 4u, 4r distortion
5 fixing elements
6 Contact surface
7 displaceable segment
8 recess
9 deformation element
10 coating
11 structured substrate surface
12 local concave curvature
12′local convex curvature
13 elevation

1-15. (canceled)

16. A method for bonding a first substrate to a second substrate, the first substrate having a primary section and the second substrate having a secondary section, wherein when the first substrate is bonded to the second substrate, a bond wave advancing along a bonding direction is formed between
a first partial portion, in which the first substrate and the second substrate are bonded, and
a second partial portion, in which the first substrate and the second substrate are still to be bonded,
wherein a subsection of the second substrate in the second partial portion is vertically offset with respect to a subsection of the second substrate in the first partial portion in a direction perpendicular to a main extension plane, and
wherein, for the relative alignment of the primary section and the secondary section with respect to one another, in particular in with respect to a direction running essentially parallel to the bonding direction, a first curvature of the first substrate and/or a second curvature of the second substrate is modified by means of a deformation system in a region adjacent to the bond wave and/or in a region including the bond wave, characterised in that during bonding by means of the deformation system a difference between the first curvature and the second curvature is kept substantially constant along the bonding direction at least in sections.

17. The method according to claim 16, wherein the deformation system comprises a plurality of deformation means arranged along the bonding direction.

18. The method according to claim 16, wherein the deformation system is changed during bonding by means of a control device.

19. The method according to claim 16, wherein the deformation system is adjusted prior to bonding.

20. The method according to claim 16, wherein for adjusting the first curvature a coating is arranged between the first substrate and a first substrate holder supporting the first substrate during the bonding process.

21. An apparatus for bonding a first substrate to a second substrate by means of a method according to claim 16, the first substrate having a primary section and the second substrate) having a secondary section, wherein the apparatus is configured so that, when the first substrate is bonded to the second substrate, a bond wave advancing along a bonding direction is formed between
a first partial portion, in which the first substrate and the second substrate are bonded, and
a second partial portion in which the first substrate and the second substrate are still to be bonded,
wherein a subsection of the second substrate in the second partial portion is vertically offset with respect to a subsection of the second substrate in the first partial portion in a direction perpendicular to a main extension plane,
wherein the apparatus for relative alignment of the primary section and the secondary section to one another, in particular with respect to a direction running essentially parallel to the bonding direction, comprises a deformation system configured to allow modification of a first curvature of the first substrate and/or a second curvature of the second substrate in a region adjacent to the bond wave and/or in a region including the bond wave, characterised in that the apparatus is designed so that, during bonding by means of the deformation system, a difference between the first curvature and the second curvature is kept substantially constant along the bonding direction at least in sections.

22. The apparatus according to claim 21, wherein said first substrate is held in a first substrate holder during bonding, said first substrate holder having fixing areas with fixing member for fixing the first substrate and/or deformation areas with deformation means for adjusting said first curvature.

23. The apparatus according to claim 21, wherein fixing areas and deformation areas alternate at least in sections along the bonding direction.

24. The apparatus according to claim 21, wherein the deformation system has a coating disposed between the first substrate and the first substrate holder during the bonding process and/or between the second substrate and the second substrate holder.

25. The apparatus according to claim 21, wherein the deformation system comprises a microstructure at a contact surface of the first substrate holder and/or second substrate holder.

26. The apparatus according to any claim 21, wherein the deformation system comprises an at least sectionally displaceable contact surface.

27. The apparatus according to any claim 21, wherein the deformation system comprises a contact surface profiled at least in sections, wherein the profiled contact surface is concave, convex and/or stepped.

28. The apparatus according to claim 21, wherein the first substrate holder and/or second substrate holder as part of the deformation system has an elevation in the edge region.
